(19) United States
(12) Patent Application Publication
(10) Pub. No.: US 2017/0344425 A1
(43) Pub. Date: Nov. 30, 2017

(54) ERROR-LADEN DATA HANDLING ON A STORAGE DEVICE

(71) Applicant: HGST Netherlands B.V., Amsterdam (NL)

(72) Inventors: Kei Akiyama, Yokohama-shi (JP); Martin Aureliano Hassner, Mountain View, CA (US); Kirk Hwang, Palo Alto, CA (US); Satoshi Yamamoto, San Jose, CA (US)

(21) Appl. No.: 15/165,669

(22) Filed: May 26, 2016

(51) Int. Cl. G06F 11/10; G11C 16/10; G06F 3/06; G11C 16/26

(52) U.S. Cl. CPC G06F 11/1076; G11C 16/26; G11C 16/10; G06F 3/0619; G06F 3/0647; G06F 3/064; G06F 3/0685

(57) ABSTRACT

In one example, the disclosure is directed to error-correcting code techniques for managing data in a hard drive. In some examples, a controller of a hard disk drive may cause data including a data band and an associated parity sector to be retrieved from non-volatile memory. The data band may include a number of virtual data tracks, and each virtual data track may include a respective plurality of sectors. The controller may determine that at least one sector of the respective plurality of sectors includes an error that renders the data in the at least one sector unreadable by the controller. The controller may send the data including the data band and the associated parity sector to a host device.

### TECHNICAL FIELD

The disclosure relates to handling error-laden data by storage devices.

### BACKGROUND

A cold storage shingled-magnetic recording (SMR) drive is utilized in archival applications that require increased capacities, which are obtained by increasing the tracks per inch (TPI) present in the drive by partially overlapping adjacent data tracks. At the same time, equivalent data integrity as present in a conventional hard disk drive is desired. For this reason, a write verify function may be implemented to increase data. reliability in conventional Cold Storage SMR drives. However, the write verify function decreases write command throughput due to an additional written data verify process. Write command throughput with the write verify function may result in an at least 55% loss of performance (e.g., throughput) when compared to a write process without the write verify function.

### SUMMARY

In one example, the disclosure is directed to a method including causing, by a controller of a hard disk drive, data including a data band and an associated parity sector to be retrieved from non-volatile memory, wherein the data band comprises a number of virtual data tracks, and wherein each virtual data track comprises a respective plurality of sectors; determining, by the controller, that at least one sector of the respective plurality of sectors includes an error that renders the data in the at least one sector unreadable by the controller; and sending, by the controller, the data including the data band and the associated parity sector to a host device.

In another example, the disclosure is directed to a hard disk drive including at least one storage medium, and a controller configured to: cause data including a data band and an associated parity sector to be retrieved from non-volatile memory, wherein the data band comprises a number of virtual data tracks, and wherein each virtual data track comprises a respective plurality of sectors; determine that at least one sector of the respective plurality of sectors includes an error that renders the data in the at least one sector unreadable by the controller; and send the data including the data band and the associated parity sector to a host device.

In another example, the disclosure is directed to a device including means for causing data including a data band and an associated parity sector to be retrieved from non-volatile memory, wherein the data band comprises a number of virtual data tracks, and wherein each virtual data track comprises a respective plurality of sectors; means for determining that at least one sector of the respective plurality of sectors includes an error that renders the data in the at least one sector unreadable by the controller; and means for sending the data including the data band and the associated parity sector to a host device.

In another example, the disclosure is directed to a computer-readable medium containing instructions that, when executed, cause a controller of a hard disk drive to cause data including a data band and an associated parity sector to be retrieved from non-volatile memory, wherein the data band comprises a number of virtual data tracks, and wherein each virtual data track comprises a respective plurality of sectors; determine that at least one sector of the respective plurality of sectors includes an error that renders the data in the at least one sector unreadable by the controller; and send the data including the data band and the associated parity sector to a host device.

In another example, the disclosure is directed to a method comprising causing, by a controller of a hard disk drive, a data block to be retrieved from non-volatile memory, wherein the data block includes an error; and sending, by the controller, the data block that includes the error to a host device.

In another example, the disclosure is directed to a hard disk drive including at least one storage medium, and a controller configured to: cause a data block to be retrieved from non-volatile memory, wherein the data block includes an error; and send the data block that includes the error to a host device.

In another example, the disclosure is directed to a device comprising means for causing a data block to be retrieved from non-volatile memory, wherein the data block includes an error; and means for sending the data block that includes the error to a host device.

In another example, the disclosure is directed to a computer-readable medium containing instructions that, when executed, cause a controller of a hard disk drive to cause a data block to be retrieved from non-volatile memory, wherein the data block includes an error; and send the data block that includes the error to a host device.

The details of one or more examples of the disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 is a conceptual and schematic block diagram illustrating an example storage environment in which a hard drive may function as a storage device for a host device, in accordance with one or more techniques of this disclosure.

FIG. 2 is a block diagram illustrating the controller and other components of the hard drive of FIG. 1 in more detail.

FIG. 3 is another block diagram illustrating a system configured to perform an example technique for reading error-laden data tracks from memory, in accordance with one or more techniques of this disclosure.

FIG. 4 is a flow diagram illustrating an example technique for a controller in writing data to memory, in accordance with one or more techniques of this disclosure.

FIG. 5 is a flow diagram illustrating an example technique for a controller in reading error-laden data tracks from memory, in accordance with one or more techniques of this disclosure.

FIG. 6 is a flow diagram illustrating an example technique for a controller in reading an error-laden data block from memory, in accordance with one or more techniques of this disclosure.

### DETAILED DESCRIPTION

In general, this disclosure describes techniques for utilizing error-correcting code (FCC) when writing and reading data in a hard disk drive, such as a cold storage shingled-magnetic recording (SMR) drive. Rather than attempting to fully recover a data block that includes errors at the controller of the SMR drive, the controller may correct up to a predetermined number error sectors in respective data blocks using FCC bits included in the respective data block and send the data blocks, including any remaining uncorrected error sectors, to a host device with the errors still present in the respective sectors of the data block. The host device, which may have a more capable processor than the controller of a SMR drive, may perform an additional ECC technique to attempt to correct the remaining uncorrected error sectors in the data block. In this way, the controller of an SMR drive may be configured to communicate data that includes one or more errors to the host device, rather than communicating an input-output (I/O) abort signal upon not being able to fully recover the data. As such, techniques of this disclosure may provide a new read command protocol in a current standard interface, such as advanced technology attachment (ATA) (e.g., serial-ATA (SATA), and parallel-ATA (PATA)), Fibre Channel, small computer system interface (SCSI), serially attached SCSI (SAS), peripheral component interconnect (PCI), PCI-express (PCIe), and non-volatile memory express (NVMe). In other examples, the techniques of this disclosure may add a new option to a current read command of any of the above protocols.

In some examples of this disclosure, a controller of a hard disk drive may cause a data block to be retrieved from non-volatile memory. The data block retrieved from memory may include an error sector. In some examples, the error sector may be an unreadable sector of a virtual data track. Rather than send the host device a mere error message, the controller of the hard disk drive may instead send the data block that includes the error to a host device.

For example, when a cold storage SMR drive implements the techniques described herein, the SMR drive may omit a write verify function, which may increase the operating efficiency (e.g., write throughput) of the cold storage SMR drive. In many write verify functions, a physical platter of the cold storage SMR drive containing the data being verified makes a full revolution for each file being verified. This is because once the data is written, the platter must spin such that the read/write head is back at the starting position of the file. When the files being verified are small, this full revolution may be greatly inefficient, as the platter must perform this rotation in addition to performing the general verify functions. Rather than (or in addition to) implementing a write verify algorithm, techniques of this disclosure enable a processor or controller to perform limited high-efficiency processes and transferring the more complicated processes onto the host device. Further, even though the verify function may alert a host device that an error was encountered in writing the data, data may still be lost over time due to various environmental factors or mechanical limitations. As such, when reading the data, the data may still have to be checked for error sectors, especially in a cold storage environment (i.e., an environment where large amounts of data are stored and may not be accessed for long periods of time). The necessity to re-check the data upon reading the data makes the write verify function superfluous in many practical situations. Rather than performing the write verify function upon writing, the techniques described herein, may increase the speed and efficiency of a controller managing the cold storage SMR drive with a minimal additional burden of storing the parity sector data.

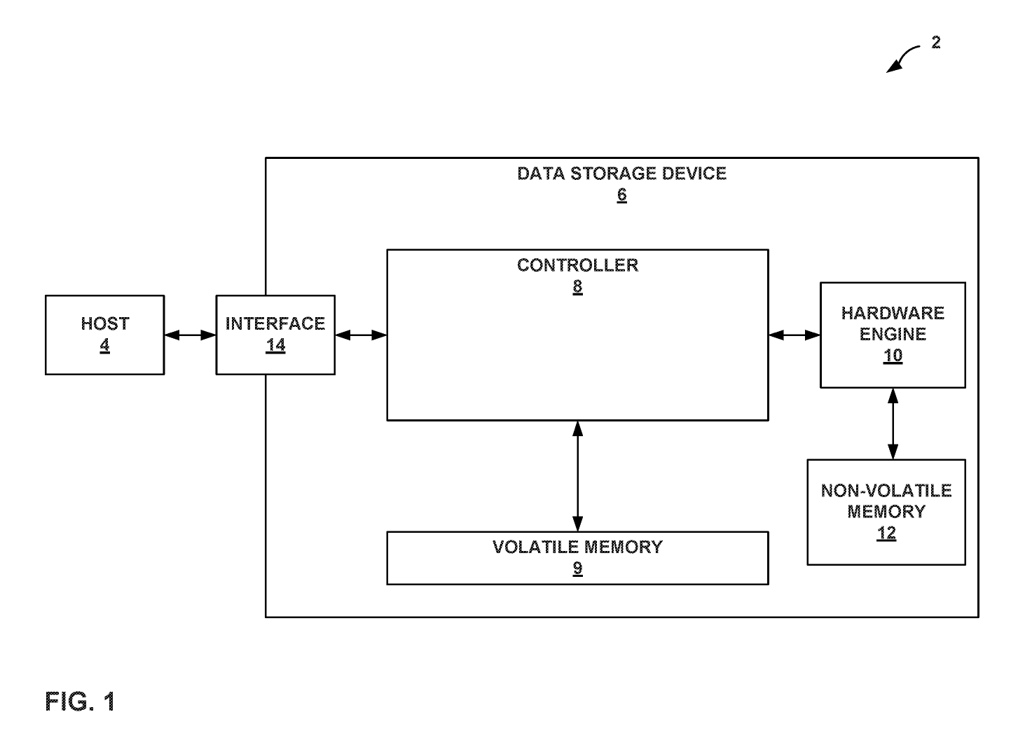

FIG. 1 is a conceptual and schematic block diagram illustrating an example storage environment 2 in which data storage device 6 may function as a storage device for host device 4, in accordance with one or more techniques of this disclosure. For instance, host device 4 may utilize non-volatile memory devices included in data storage device 6, such as non-volatile memory (NVM) 12, to store and retrieve data. In some examples, storage environment 2 may include a plurality of storage devices, such as data storage device 6, which may operate as a storage array. For instance, storage environment 2 may include a plurality of hard drives 6 configured as a redundant array of inexpensive/independent disks (RAID) that collectively function as a mass storage device for host device 4. While techniques of this disclosure generally refer to storage environment 2 and data storage device 6, techniques described herein may be performed in any storage environment that utilizes tracks of data.

Storage environment 2 may include host device 4 which may store and/or retrieve data to and/or from one or more storage devices, such as data storage device 6. As illustrated in FIG. 1, host device 4 may communicate with data storage device 6 via interface 14. Host device 4 may include any of a wide range of devices, including computer servers, network attached storage (NAS) units, desktop computers, notebook (i.e., laptop) computers, tablet computers, set-top boxes, telephone handsets such as so-called “smart” phones, so-called “smart” pads, televisions, cameras, display devices, digital media players, video gaming consoles, video streaming device, and the like. Typically, host device 4 includes any device having a processing unit, which may refer to any form of hardware capable of processing data and may include a general purpose processing unit (such as a central processing unit (CPU), dedicated hardware (such as an application specific integrated circuit (ASIC)), configurable hardware such as a field programmable gate array (FPGA) or any other form of processing unit configured by way of software instructions, microcode, firmware, or the like.

As illustrated in FIG. 1 data storage device 6 may include a controller 8, a volatile memory 9, a hardware engine 10, NVM 12, and an interface 14. In some examples, data storage device 6 may include additional components not shown in FIG. 1 for ease of illustration purposes. For example, data storage device 6 may include power delivery components, including, for example, a capacitor, super capacitor, or battery; a printed board (PB) to which components of data storage device 6 are mechanically attached and which includes electrically conductive traces that electrically interconnect components of data storage device 6, and the like. In some examples, the physical dimensions and connector configurations of data storage device 6 may conform to one or more standard form factors. Some example standard form factors include, but are not limited to, 3.5″ hard disk drive (HDD), 2.5″ HDD, or 1.8″ HDD.

In some examples, volatile memory 9 may store information for processing during operation of data storage device 6. In some examples, volatile memory 9 is a temporary memory, meaning that a primary purpose of volatile memory 9 is not long-term storage. Volatile memory 9 on data storage device 6 may configured for short-term storage of information as volatile memory and therefore not retain stored contents if powered off. Examples of volatile memories include random access memories (RAM), dynamic random access memories (DRAM), static random access memories (SRAM), and other forms of volatile memories known in the art.

In some examples, data storage device 6 may be an SMR drive. With SMR, tracks are written to NVM 12 and successively written data tracks partially overlap the previously written data tracks, which typically increases the data density of NVM 12 by packing the tracks closer together. In some examples in which data storage device 6 is an SMR drive, data storage device 6 may also include portions of NVM 12 that do not include partially overlapping data tracks and are thus configured to facilitate random writing and reading of data. To accommodate the random access zones, portions of NVM 12 may have tracks spaced farther apart than in the sequential. SMR zone,

NVM 12 may be configured to store larger amounts of information than volatile memory 9. NVM 12 may further be configured for long-term storage of information as non-volatile memory space and retain information after power on/off cycles. Examples of non-volatile memories include magnetic media, optical disks, floppy disks, flash memories, or forms of electrically programmable memories (EPROM) or electrically erasable and programmable memories (EEPROM). NVM 12 may be one or more magnetic platters in data storage device 6, each platter containing one or more regions of one or more tracks of data.

Data storage device 6 may include interface 14 for interfacing with host device 4. Interface 14 may include one or both of a data bus for exchanging data with host device 4 and a control bus for exchanging commands with host device 4. Interface 14 may operate in accordance with any suitable protocol. For example, interface 14 may operate in accordance with one or more of the following protocols: advanced technology attachment (ATA) serial-ATA (SATA), and parallel-ATA (PATA)), Fibre Channel, small computer system interface (SCSI), serially attached SCSI (SAS), peripheral component interconnect (PCI), PCI-express (PCIe), and non-volatile memory express (NVMe). The electrical connection of interface 14 (e.g., the data bus, the control bus, or both) is electrically connected to controller 8, providing electrical connection between host device 4 and controller 8, allowing data to be exchanged between host device 4 and controller 8. In some examples, the electrical connection of interface 14 may also permit data storage device 6 to receive power from host device 4.

In the example of FIG. 1. data storage device 6 includes hardware engine 10, which may represent the hardware responsible for interfacing with the NVM 12. Hardware engine 10 may, in the context of a platter-based hard drive such as an SMR drive, represent the magnetic read/write head and the accompanying hardware to configure, drive, and process the signals sensed by the magnetic read/write head.

Data storage device 6 includes controller 8, which may manage one or more operations of data storage device 6. Controller 8 may interface with host device 4 via interface 14 and manage the storage of data to and the retrieval of data from NVM 12 accessible via hardware engine 10. Controller 8 may, as one example, manage writes to and reads from the memory devices, e.g., volatile memory 9 and NVM 12. In some examples, controller 8 may be a hardware controller. In other examples, controller 8 may be implemented into data storage device 6 as a software controller. Controller 8 may further include one or more features that may perform techniques of this disclosure, such as atomic write-in-place module 16.

Host 4 may execute software, such as the above noted operating system, to manage interactions between host 4 and hardware engine 10. The operating system may perform arbitration in the context of multi-core CPUs, where each core effectively represents a different CPU, to determine which of the CPUs may access hardware engine 10. The operating system may also perform queue management within the context of a single CPU to address how various events, such as read and write requests in the example of data storage device 6, issued by host 4 should be processed by hardware engine 10 of data storage device 6.

In accordance with the techniques of this disclosure, when controller 8 is causing data to be written to NVM 12, controller 8 may receive a data band and a parity sector (e.g., an ECC parity sector) from host device 4. The data band may include a number of virtual tracks. A virtual track is a range of logical block addresses assigned to correspond with physical portions of NVM 12 and includes a plurality of sectors, each of which may correspond to one or more logical block addresses, depending on the sizes of the respective logical block address and sector. Each element of the data band may be a data sector, with each data sector including a certain number of bytes. For instance, each data sector may include 4096 bytes. Host 8 may define the data band and communicate the data band to controller 8 via interface 14. Controller 8 may assign the data band to be written to NVM 12.

The data band may have a number of rows equal to the number of virtual tracks and a number of columns equal to a number of sectors per virtual track. For instance, the data band may have 8 rows if the data band contains 8 virtual tracks of data. In some instances, each virtual data track may have as many as 512 sectors per track, although other examples may have more sectors per track or fewer sectors per track as necessary for the unique example. The number of virtual data tracks in the data band may be predefined or selectable by host device 4 prior to executing the techniques described herein. In some examples, the number of virtual data tracks in the data band is constant.

The parity sector may include parity data for the data band, computed by host device 4. In some examples, the parity sector may have dimensions such that the number of rows is equal to the number of integrated/ECC correctable tracks and that the number of columns is equal to a number of parity bits at each integrated track. Hence, the number of rows and columns of the parity sector may define a number of sectors in data band that may he recovered by host 4 using the ECC technique executed by host device 4. Controller 8 may cause the data band and the associated parity sector to be written to NVM 12 by hardware engine 10.

In response to a read request received from host device 4, controller may cause data to be read from NVM 12. The data may include a data band and an associated parity sector. As described above, the data band may include a number of virtual data tracks, with each virtual data track including a respective plurality of sectors. In the example of FIG. 1, the data band may have 8 rows and 512 columns. In some examples, each virtual data track of the number of virtual data tracks may include a plurality of readable sectors.

Controller 8 may determine that at least one sector of the respective plurality of sectors includes an error. Each error may render the data in the at least one sector unreadable by controller 8. In some examples, controller 8 may further determine an identity of each respective sector of the at least one sector that includes at least one error that renders at least a portion of the data in the at least one sector unreadable. For instance, controller 8 may determine that track 1 of the data band may have unreadable sectors at columns 74, 212, and 389. Controller 8 may further determine that track 3 of the data band may have unreadable sectors at columns 148 and 422. As such, controller 8 may determine that the data band includes five error sectors at respective positions of the data band. In some such examples, controller 8 may create an error location list that includes a logical block address corresponding to each respective sector of the at least one sector that includes at least one error that renders the data in the at least one sector unreadable by controller 8. The logical block address (LBA) may reference the error sector, e.g., a direct address of the memory location or a position in the data band. In the example of FIG. 1, controller 8 may create the error location list with 5 LBAs, with each LBA referencing the respective determined positions, i.e., track 1 column 74, track 1 column 212, track 1 column 389, track 3 column 148, and track 3 column 422.

Controller 8 may send the data including the data band with the error in the at least one sector and the associated parity sector to host device 4. In the example of FIG. 1, controller 8 may send the data band with error sectors at track 1 column 74, track 1 column 212, track 1 column 389, track 3 column 148, and track 3 column 422 to host device 4. as well as the parity sector. In some examples, where controller 8 creates the error location list referencing the positions in the data band for each of the at least one error, controller 8 may further send the error location list to host device 4. As such, host device 4 may bypass processes that determine where error sectors exist in the data band. In the example of FIG. 1, controller 8 may send the data band with error sectors at track 1 column 74, track 1 column 212, track 1 column 389, track 3 column 148, and track 3 column 422 to host device 4. As such, controller 8 may further send the error location list with LBAs corresponding to the positions of track 1 column 74, track 1 column 212, track 1 column 389, track 3 column 148, and track 3 column 422 to host device 4. Host device 4 may then implement an ECC technique that utilizes the parity sector to recover the unreadable sectors.

By using the techniques described above, controller 8 may omit the inefficient write verify function, which may increase the operating efficiency (e.g., write throughput) of the hard drive (e.g., an SMR disk drive). Rather than (or in addition to) implementing a write verify algorithm, techniques of this disclosure enable a processor or controller to perform limited high-efficiency processes (e.g., reading the data and determining the location of unreadable sectors) and transferring the more complicated processes (e.g., the non-track level ECC procedures) onto the host device. Further, even though the write verify function may alert a host device that an error was encountered in writing the data, data may still be lost over time due to various environmental factors or mechanical limitations. As such, when reading the data, the data may still have to be checked for errors, especially in a cold storage environment (i.e., an environment where large amounts of data are stored and may not be accessed for long periods of time). The necessity to re-check the data upon reading the data makes the write verify function superfluous in many practical situations. Rather than performing the write verify function upon writing, the techniques described herein, which may be used to recover various sectors in tracks of data, may increase the speed and efficiency of a controller managing the cold storage SMR drive with a minimal additional burden of storing the parity sector data. Further, by sending the LBAs referencing the positions of the error sectors in the data band, controller 8 may further reduce processing times and power consumption of host device 4 in performing ECC techniques.

In some examples, a virtual data track in the data band includes at least one controller-correctable error different from the determined error in the at least one sector. In such examples, the techniques described herein may be combined with other ECC techniques, such as HDD track ECC. For instance, prior to sending the data including the data band and the associated parity sector to host device 4, controller 8 may first perform a bock ECC process (such as HDD track ECC) to correct the at least one controller-correctable error and recover a predefined number of error sectors in each block of data (e.g., up to 4 error sectors in a block) in the data hand. In some examples, a block of data may be equivalent to a sector. In other examples, a sector of data may be a different unit than a block of data. However, track FCC techniques may not be sufficient to recover all sectors that contain an error, which may result in controller 8 determining some sectors to remain unreadable, as described above. In examples in which controller 8 implements a track FCC technique, in addition to the parity sector received from host device 4, when controller 8 initially causes the data band to be written to NVM 12, controller 8 may also determine track ECC parity bits to be used in track ECC techniques implemented by controller 8 and write these parity bits to NVM 12 with the associated block of data.

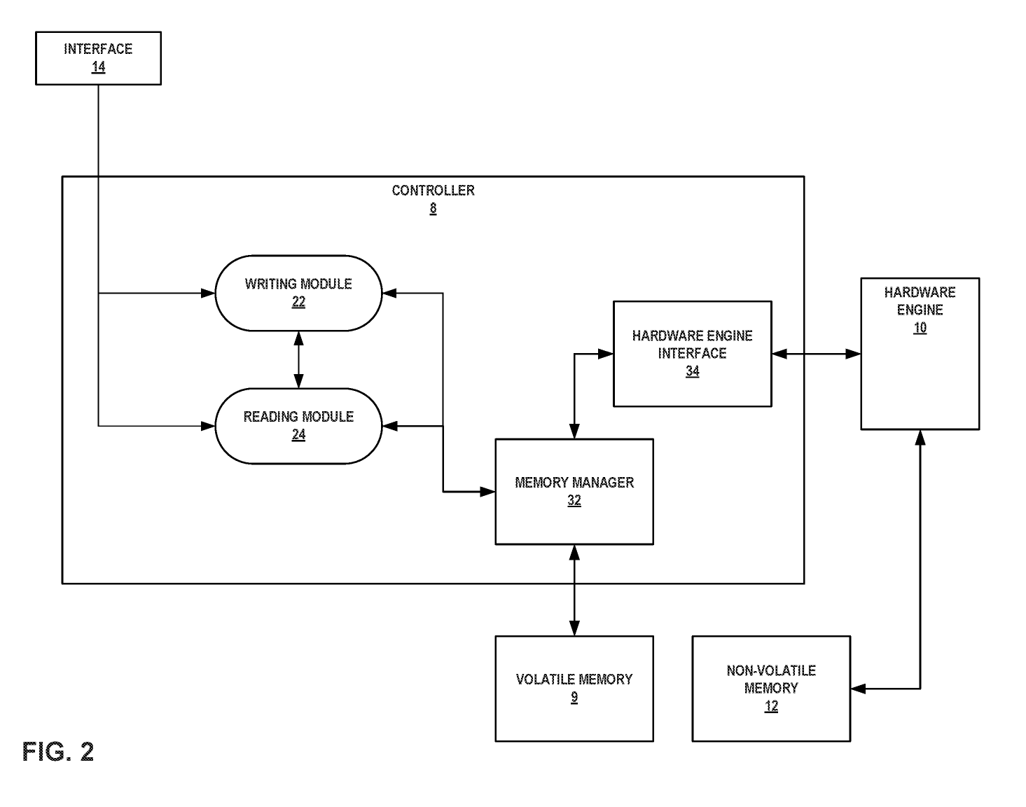

FIG. 2 is a block diagram illustrating controller 8 and other components of data storage device 6 of FIG. 1 in more detail. In the example of FIG. 2, controller 8 includes interface 14, write module 22, read module 24, memory manager unit 32, and hardware engine interface unit 34. Memory manager unit 32 and hardware engine interface unit 34 may perform various functions typical of a controller on a hard drive. For instance, hardware engine interface unit 34 may represent a unit configured to facilitate communications between the hardware controller 8 and the hardware engine 10. Hardware engine interface unit 34 may present a standardized or uniform way by which to interface with hardware engine 10. Hardware engine interface 34 may provide various configuration data and events to hardware engine 10, which may then process the event in accordance with the configuration data, returning various different types of information depending on the event. In the context of an event requesting that data be read (e.g., a read request), hardware engine 10 may return the data to hardware engine interface 34, which may pass the data to memory manager unit 32. Memory manager unit 32 may store the read data to volatile memory 9 and return a pointer or other indication of where this read data is stored to hardware engine interface 34. In the context of an event involving a request to write data (e.g. a write request), hardware engine 10 may return an indication that the write has completed to hardware engine interface unit 34. In this respect, hardware engine interface unit 34 may provide a protocol and handshake mechanism with which to interface with hardware engine 10.

Controller 8 includes various modules, including write module 22 and read module 24. The various modules of controller 8 may be configured to perform various techniques of this disclosure, including the technique described above with respect to FIG. 1. Write module 22 and read module 24 may perform operations described herein using software, hardware, firmware, or a mixture of hardware, software, and firmware residing in and/or executing on data storage device 6.

In accordance with the techniques of this disclosure, when controller 8 is causing data to be written to NVM 12, write module 22 may receive a data band and a parity sector (e.g., an ECC parity sector) from host device 4. The data band may include a number of virtual tracks. A virtual track is a range of logical block addresses assigned to correspond with physical portions of NVM 12 and includes a plurality of sectors, each of which may correspond to one or more logical block addresses, depending on the sizes of the respective logical block address and sector. Host device 4 may define the data. band and communicate the data band to controller 8 via interface 14. Write module 22 may assign the data to be written to NVM 12. The data band may have a number of rows equal to the number of virtual tracks and a number of columns equal to a number of sectors per virtual track.

For instance, the data band may have 128 rows if the data band contains 128 virtual tracks of data. In some instances, each virtual data track may have as many as 512 sectors per track, although other examples may have more sectors per track or fewer sectors per track as necessary for the unique example, as well as more or less virtual tracks of data residing within the data band. The number of virtual data tracks in the data band may be predefined or selectable by host device 4 prior to executing the techniques described herein. In some examples, the number of virtual data tracks in the data band is constant for data storage device 6. In some examples, the parity sector may have dimensions such that the number of rows is equal to the number of integrated/ECC correctable tracks (i.e., the number of rows in the integration matrix) and that the number of columns is equal to a number of parity bits at each integrated track. Write module 22 may then write the data band and the parity sector to NVM 12.

In response to a read request received from host device 4, read module 24 of controller 8 may cause data to be read from NVM 12. The data may include a data band and an associated parity sector. As described above, the data band may include a number of virtual data tracks, with each virtual data track including a respective plurality of sectors. In the example of FIG. 2, the data band may have 128 rows and 512 columns. In some examples, each virtual data track of the number of virtual data tracks may include a plurality of readable sectors.

Read module 24 determine that at least one sector of the respective plurality of sectors includes an error. Each error may render the data in the at least one sector unreadable by read module 24. In some examples, read module 24 may further determine an identity of each respective sector of the at least one sector that includes at least one error that renders the data in the at least one sector unreadable. For instance, read module 24 may determine that track 19 of the data band may have unreadable sectors at columns 32 through 35, 212, and 389. Read module 24 may further determine that track 34 of the data band may have unreadable sectors at columns 75 through 79, 148, 256, and 422, and that track 95 may have unreadable sectors at columns 2, 4, 6, and 9. As such, read module 24 may determine that the data band includes eighteen error sectors at respective positions of the data band. In some such examples, read module 24 may create an error location list containing LBAs corresponding to each respective sector of the at least one sector that includes at least one error that renders the data in the at least one sector unreadable by controller 8. In the example of FIG. 2, read module 24 may create an error location list with eighteen LBAs, with each LBA referencing the respective determined positions, i.e., track 19 column 32, track 19 column 33, track 19 column 34, track 19 column 35, track 19 column 212, track 19 column 389, track 34 column 75, track 34 column 76, track 34 column 77, track 34 column 78, track 34 column 79, track 34 column 148, track 34 column 256, track 34 column 422, track 95 column 2, track 95 column 4, track 95 column 6, and track 95 column 9.

Read module 24 may send the data including the data band with the error in the at least one sector and the associated parity sector to host device 4 in the example of FIG. 2, read module 24 may send the data band with error sectors at track 19 column 32, track 19 column 33, track 19 column 34, track 19 column 35, track 19 column 212, track 19 column 389, track 34 column 75, track 34 column 76, track 34 column 77, track 34 column 78, track 34 column 79, track 34 column 148, track 34 column 256, track 34 column 422, track 95 column 2, track 95 column 4, track 95 column 6, and track 95 column 9 to host device 4, as well as the parity sector. In some examples, where read module 24 creates an error location list referencing the positions in the data band for each of the at least one error, controller 8 may further send the error location list to host device 4. As such, host device 4 may bypass processes that determine where error sectors exist in the data band. In the example of FIG. 2, read module 24 may send the data band with error sectors at track 19 column 32, track 19 column 33, track 19 column 34, track 19 column 35, track 19 column 212, track 19 column 389, track 34 column 75, track 34 column 76, track 34 column 77, track 34 column 78, track 34 column 79, track 34 column 148, track 34 column 256, track 34 column 422, track 95 column 2, track 95 column 4, track 95 column 6. and track 95 column 9 to host device 4. As such, controller 8 may further send the error location list with LBAs corresponding to the positions of track 19 column 32, track 19 column 33, track 19 column 34, track 19 column 35, track 19 column 212, track 19 column 389, track 34 column 75, track 34 column 76, track 34 column 77, track 34 column 78, track 34 column 79, track 34 column 148, track 34 column 256, track 34 column 422, track 95 column 2, track 95 column 4, track 95 column 6, and track 95 column 9 to host device 4. Host device 4 may then implement an ECC technique that utilizes the parity sector to recover the unreadable sectors.

In some examples, a virtual data track in the data band includes at least one controller-correctable error different from the determined error in the at least one sector. In such examples, the techniques described herein may be combined with other ECC techniques, such as HDD track ECC. For instance, prior to sending the data including the data band and the associated parity sector to host device 4, read module 24 may first perform a bock ECC process (such as HDD track ECC) to correct the at least one controller-correctable error and recover a predefined number of error sectors in each block of data (e.g., up to 4 error sectors in a block) in the data band. In some examples, a block of data may be equivalent to a sector. In other examples, a sector of data may be a different unit than a block of data. However, track ECC techniques may not be sufficient to recover all of the sectors that contain an error, which may result in controller 8 determining that some sectors remain unreadable, as described above. In examples in which controller 8 implements a track ECC technique, in addition to the parity sector received from host device 4, when controller 8 initially causes the data band to be written to NVM 12, controller 8 may also determine track ECC parity bits to be used in track ECC techniques implemented by controller 8 and write these parity bits to NVM 12 with the associated block of data.

In the example of FIG. 2, the error sectors at positions track 19 columns 32-35, track 35 columns 75-58, and track 95 columns 2, 4, 6, and 9 may be controller-correctable error sectors. In such an example, read module 24 may perform a track ECC process on the data band. This process may result in read module 24 correcting the error sectors at positions track 19 columns 32-35, track 35 columns 75-58, and track 95 columns 2, 4, 6, and 9. In the example where LBAs are determined that reference the positions of the error sectors, read module 24 may either delete these entries in the error location list if read module 24 has already determined the LBAs, or refrain from creating these entries. In any case, after performing the track ECC process, read module 24 may send the data band including the remainder of the plurality of error sectors not corrected by the track ECC process to host device 4. In the example of FIG. 2, read module 24 would send the updated data band including error sectors only at positions track 19 column 212, track 19 column 389, track 34 column 148, track 34 column 256, and track 34 column 422 to host device 4. In examples where read module 24 further creates an error location list with LBAs referencing these positions, read module 24 may send the error location list corresponding to the positions of track 19 column 212, track 19 column 389, track 34 column 148, track 34 column 256, and track 34 column 422 to host device 4.

By using the techniques described above, controller 8 may omit the inefficient write verify function, which may increase the operating efficiency (e.g., write throughput) of the hard drive (e.g., an SMR disk drive). Rather than (or in addition to) implementing a write verify algorithm, techniques of this disclosure enable a processor or controller to perform limited high-efficiency processes (e.g., reading the data and determining the location of unreadable sectors) and transferring the more complicated processes (e.g., the non-track level ECC procedures) onto the host device. Further, even though the write verify function may alert a host device that an error was encountered in writing the data, data may still be lost over time due to various environmental factors or mechanical limitations. As such, when reading the data, the data may still have to be checked for errors, especially in a cold storage environment (i.e., an environment where large amounts of data are stored and may not be accessed for long periods of time). The necessity to re-check the data upon reading the data makes the write verify function superfluous in many practical situations. Rather than performing the write verify function upon writing, the techniques described herein, which may be used to recover various sectors in tracks of data, may increase the speed and efficiency of a controller managing the cold storage SMR drive with a minimal additional burden of storing the parity sector data. Further, by sending the LBAs referencing the positions of the error sectors in the data band, controller 8 may further reduce processing times and power consumption of host device 4 in performing ECC techniques.

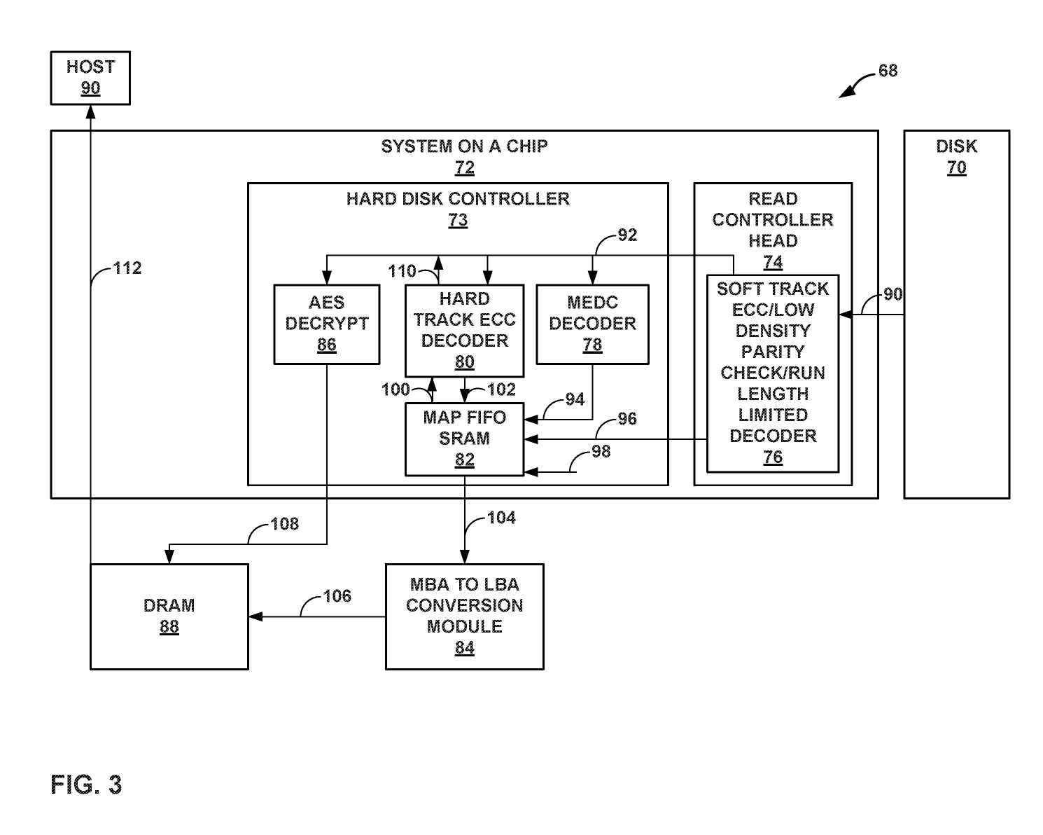

FIG. 3 is another block diagram illustrating a system 68 configured to perform an technique for reading error-laden data tracks from memory, in accordance with one or more techniques of this disclosure. System 68 includes disk 70, system on a chip (SoC) 72, media block address (MBA) to logical block address (LBA) conversion module 84, dynamic random access memory (DRAM) 88, and host 90. Disk 70 may be a storage medium akin to volatile memory 9 or non-volatile memory 12 of FIGS. 1 and 2. SoC 72 further includes read controller head (RCH) 74 and hard disk controller (HDC) 73. HDC 73 may be a controller similar to controller 8 of FIGS. 1 and 2. Read controller head 74 may further include soft track ECC/low density parity check (LDPC)/run length limited (RLL) decoder 76.

In some examples, HDC 73 may also include one or more of media error detection code (MEDC) decoder 78, hard track ECC decoder 80, map first-in-first-out (FIFO) static random access memory (SRAM) 82, and advanced encryption standard (AES) decryption module 84. MEDC decoder 78 may receive write data (also called user data) and generate the Data Sector which is the data plus the calculated ECC checks for the data. Hard track ECC decoder 80 may use the data and the checks generated by the MEDC along with the cumulative sums in its buffer to generate the output of additional parity sectors P₁ . . . Pᵣ as the sum of weighted data sectors for the track.

In accordance with techniques of this disclosure, RCH 74 may receive a signal sensed by a read head from disk 70 (90), where soft track ECC/LDPC/RLL decoder 76 may attempt to process the data. RCH 74 may further relay the data to MEDC decoder 78 and hard track FCC decoder 80 (92). MEDC decoder 78 may attempt to decode the received data. If MEDC decoder fails to decode at least a portion of the received data, MEDC decoder 78 may send an MEDC decode failure message to map FIFO SRAM 82 (94). If soft track ECC/LDPC/RLL decoder 74 fails to decode at least a portion of the received data, soft track ECC/LDPC/RLL decoder 74 may send an LDPC decode failure message to map FIFO SRAM 82 (96). A processor operatively connected to map FIFO SRAM 82 may use the MEDC decode failure message and the LDPC decode failure message to determine MBAs for the unreadable portions of the received data (98)

Hard track ECC decoder 80 may access the retrieved MBAs for the unreadable portions of the received data from hard track ECC decoder 80 (100). Hard track ECC decoder 80 may perform a track FCC process on the data in an attempt to recover one or more unreadable sectors of the received data. Upon completion of the track ECC process, hard track ECC decoder 80 may notify map FIFO SRAM 82 of which sectors were recovered in the track FCC process (102). Hard track FCC decoder 80 may further send the updated data (including the initially readable data, the recovered data, and any remaining unreadable sectors) to AES decryption module 86 (110), which decrypts the data according to AES.

The processor operatively connected to map FIFO SRAM 82 may receive the data block that contains some recovered sectors and some sectors that remain unreadable (i.e., that still contain an error) from the hard track FCC decoder 80. Map FIFO SRAM 82 may determine which sectors in the received data still include an error, even after the track ECC process is complete. Map FIFO may send the MBAs for these sectors to MBA to LBA conversion module 84 (104). MBA to LBA conversion module 84 may convert these received MBAs to LBAs to create an unreadable LBA-location list. MBA to LBA conversion module 84 stores this list to DRAM 88 (106).

A processor operatively connected to DRAM 88 may then send the updated date (including the initially readable data, the recovered data, and any remaining unreadable sectors) received from AES decryption module 86 and the unreadable LBA-location list received from MBA to LBA conversion module 84 to host 90 (112).

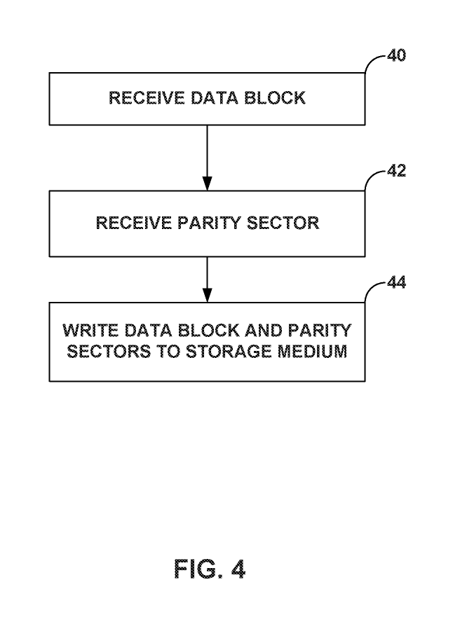

FIG. 4 is a flow diagram illustrating an exemplary operation of a controller in writing data to memory, in accordance with one or more techniques of this disclosure. For the purposes of illustration only, reference will be made to structures of FIG. 1 in describing the functionality performed in accordance with the techniques of this disclosure.

In accordance with the techniques of this disclosure, when controller 8 is causing data to be written to NVM 12, controller 8 may receive a data band and a parity sector (e.g., an FCC parity sector) from host device 4 (40). The data band may include a number of virtual tracks. A virtual track is a range of logical block addresses assigned to correspond with physical portions of NVM 12 and includes a plurality of sectors, each of which may correspond to one or more logical block addresses, depending on the sizes of the respective logical block address and sector. Host 8 may define the data band and communicate the data band to controller 8 via interface 14. Controller 8 may assign the data band to be written to NVM 12.

The data band may have a number of rows equal to the number of virtual tracks and a number of columns equal to a number of sectors per virtual track. For instance, the data band may have 128 rows if the data band contains 128 virtual tracks of data. In some instances, each virtual data track may have as many as 512 sectors per track, although other examples may have more sectors per track or fewer sectors per track as necessary for the unique example. The number of virtual data tracks in the data band may be predefined or selectable by host 4 prior to executing the techniques described herein. In some examples, the number of virtual data tracks in the data band is constant for data storage device 6.

The parity sector may include parity data for the data band, computed by host device 4. In some examples, the parity sector may have dimensions such that the number of rows is equal to the number of integrated/ECC correctable tracks and that the number of columns is equal to a number of parity bits at each integrated track. Hence, the number of rows and columns of the parity sector may define a number of sectors in data band that may be recovered by host 4 using the ECC technique executed by host device 4. Controller 8 may cause the data band and the associated parity sector to be written to NVM 12 by hardware engine 10 (42).

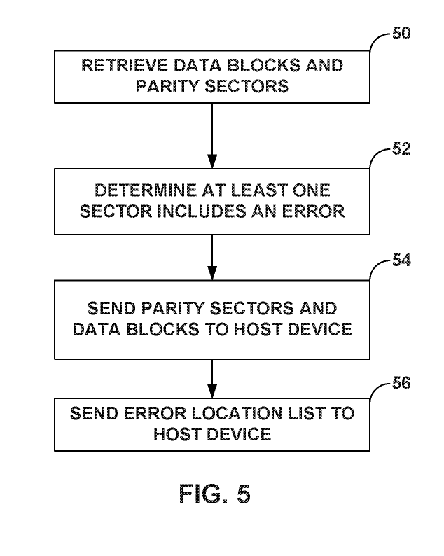

FIG. 5 is a flow diagram illustrating an exemplary operation of a controller in reading error-laden data tracks from memory, in accordance with one or more techniques of this disclosure. For the purposes of illustration only, reference will be made to structures of FIG. 1 in describing the functionality performed in accordance with the techniques of this disclosure.

In accordance with the techniques of this disclosure, in response to a read request received from host device 4, controller may cause data to be read from NVM 12 (50). The data may include a data band and an associated parity sector (e.g., an ECC parity sector). As described above, the data band may include a number of virtual data tracks, with each virtual data track including a respective plurality of sectors. In the example of FIG. 1, the data band may have 128 rows and 512 columns. In some examples, each virtual data track of the number of virtual data tracks may include a plurality of readable sectors.

Controller 8 determine that at least one sector of the respective plurality of sectors includes an error (52). Each error may render the data in the at least one sector unreadable by controller 8. In some examples, controller 8 may further determine an identity of each respective sector of the at least one sector that includes at least one error that renders the data in the at least one sector unreadable. For instance, controller 8 may determine that track 19 of the data band may have unreadable sectors at columns 32 through 35, 212, and 389. Controller 8 may further determine that track 34 of the data band may have unreadable sectors at columns 75 through 79, 148, 256, and 422, and that track 95 may have unreadable sectors at columns 2, 4, 6, and 9. As such, controller 8 may determine that the data band includes eighteen error sectors at respective positions of the data band. In some such examples, controller 8 may create a respective error location list with LBAs corresponding to each respective sector of the at least one sector that includes at least one error that renders the data in the at least one sector unreadable by controller 8. In the example of FIG. 5, controller 8 may create an error location list with eighteen LBAs, with each respective LBA referencing the respective determined positions, i.e., track 19 column 32, track 19 column 33, track 19 column 34, track 19 column 35, track 19 column 212, track 19 column 389, track 34 column 75, track 34 column 76, track 34 column 77, track 34 column 78, track 34 column 79, track 34 column 148, track 34 column 256, track 34 column 422, track 95 column 2, track 95 column 4, track 95 column 6, and track 95 column 9.

Controller 8 may send the data including the data band with the error in the at least one sector and the associated parity sector to host device 4 (54). In the example of FIG. 5, controller 8 may send the data band with error sectors at track 19 column 32, track 19 column 33, track 19 column 34, track 19 column 35, track 19 column 212, track 19 column 389, track 34 column 75, track 34 column 76, track 34 column 77, track 34 column 78, track 34 column 79, track 34 column 148, track 34 column 256, track 34 column 422, track 95 column 2, track 95 column 4, track 95 column 6, and track 95 column 9 to host device 4, as well as the parity sector. In some examples, where controller 8 creates the error location list with LBAs referencing the positions in the data band for each of the at least one error, controller 8 may further send the error location list to host device 4 (56). As such, host device 4 may bypass processes that determine where error sectors exist in the data band. In the example of FIG. 5, controller 8 may send the data band with error sectors at track 19 column 32, track 19 column 33, track 19 column 34, track 19 column 35, track 19 column 212, track 19 column 389, track 34 column 75, track 34 column 76, track 34 column 77, track 34 column 78, track 34 column 79, track 34 column 148, track 34 column 256, track 34 column 422, track 95 column 2, track 95 column 4, track 95 column 6, and track 95 column 9 to host device 4. As such, controller 8 may further send the LBAs corresponding to the positions of track 19 column 32, track 19 column 33, track 19 column 34, track 19 column 35, track 19 column 212, track 19 column 389, track 34 column 75, track 34 column 76, track 34 column 77, track 34 column 78, track 34 column 79, track 34 column 148, track 34 column 256, track 34 column 422, track 95 column 2, track 95 column 4, track 95 column 6, and track 95 column 9 to host device 4. Host device 4 may then implement an ECC technique that utilizes the parity sector to recover the unreadable sectors.

In some examples, a virtual data track in the data band includes at least one controller-correctable error different from the determined error in the at least one sector. In such examples, the techniques described herein may be combined with other ECC techniques, such as HDD track ECC. For instance, prior to sending the data including the data band and the associated parity sector to host device 4, controller 8 may first perform a bock ECC process (such as HDD track ECC) to correct the at least one controller-correctable error and recover a predefined number of error sectors in each block of data (e.g., up to 4 error sectors in a block) in the data band. In some examples, a block of data may be equivalent to a sector. In other examples, a sector of data may be a different unit than a block of data. However, track ECC techniques may not be sufficient to recover all sectors that contain an error, which may result in controller 8 determining that some sectors remain unreadable, as described above. In examples in which controller 8 implements a track ECC technique, in addition to the parity sector received from host device 4. when controller 8 initially causes the data band to be written to NVM 12, controller 8 may also determine track ECC parity sectors to be used in track ECC techniques implemented by controller 8 and write these parity sectors to NVM 12 with the associated block of data. In the example of FIG. 5, the error sectors at positions track 19 columns 32-35, track 35 columns 75-58, and track 95 columns 2, 4, 6, and 9 may be controller-correctable error sectors.

In such an example, controller 8 may perform a track ECC process on the data band. This process may result in controller 8 correcting the error sectors at positions track 19 columns 32-35, track 35 columns 75-58, and track 95 columns 2, 4, 6, and 9. In the example where LBAs are determined that reference the positions of the error sectors, controller 8 may either delete these entries if controller 8 has already determined the LBAs, or refrain from creating entries for these LBAs in the error location list. In any case, after performing the track ECC process, controller 8 may send the data band including the remainder of the plurality of error sectors not corrected by the track ECC process to host device 4. In the example of FIG. 4, controller 8 would send the updated data band including error sectors only at positions track 19 column 212, track 19 column 389, track 34 column 148, track 34 column 256, and track 34 column 422 to host device 4. In examples where controller 8 further creates an error location list with LBAs referencing these positions, controller 8 may send the error location list with LBAs corresponding to the positions of track 19 column 212, track 19 column 389, track 34 column 148, track 34 column 256, and track 34 column 422 to host device 4.

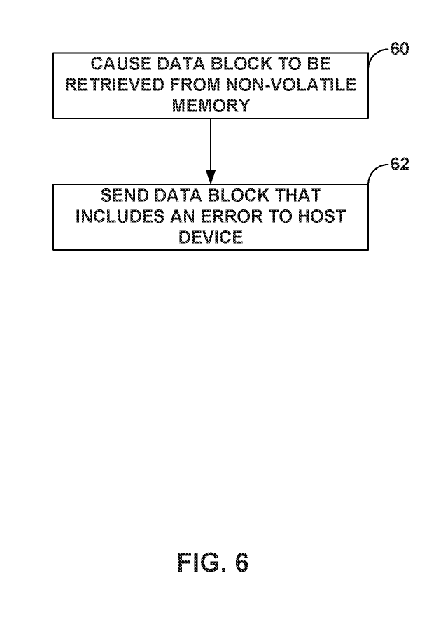

FIG. 6 is a flow diagram illustrating an exemplary operation of a controller in reading an error-laden data block from memory, in accordance with one or more techniques of this disclosure. For the purposes of illustration only, reference will be made to structures of FIG. 1 in describing the functionality performed in accordance with the techniques of this disclosure.

In accordance with techniques of this disclosure, controller 8 of hard disk drive 6 may cause a data block to be retrieved from non-volatile memory (60). The data block retrieved from memory may include an error. In some examples, the data block may be an unreadable sector of a virtual data track. Rather than send host device 4 a mere error message, controller 8 may instead send the data block that includes the error to host device 4 (62).

In some examples controller 8 may further send an indication to host device 4 that the data block includes the error. In some instances, the indication may be a flag. In some such instances, one value for the flag may indicate that the data block includes an error, and a second value for the flag may indicate that the data block does not include an error. In other instances, the absence of the flag may indicate that the data block does not include an error, and the presence of the flag may indicate that the data block does include an error. In other examples, the indication may be a logical block address indicating a position of the data block in a data band.

### EXAMPLE 1

A method comprising: causing, by a controller of a hard disk drive, data including a data band and an associated parity sector to be retrieved from non-volatile memory, wherein the data band comprises a number of virtual data tracks, and wherein each virtual data track comprises a respective plurality of sectors; determining, by the controller, that at least one sector of the respective plurality of sectors includes an error that renders the data in the at least one sector unreadable by the controller; and sending, by the controller, the data including the data band and the associated parity sector to a host device.

### EXAMPLE 2

The method of example 1, further comprising: determining, by the controller, a logical block address of each respective sector of the at least one sector that includes at least one error that renders the data in the at least one sector unreadable by the controller; and creating, by the controller, an error location list comprising each of the determined logical block addresses.

### EXAMPLE 3

The method of example 2, further comprising: sending, by the controller, the error location list to the host device.

### EXAMPLE 4

The method of any of examples 1-3, wherein a portion of the determined errors in the at least one sector a virtual data track in the data band includes at least one controller-correctable error different from the determined error in the at least one sector, the method further comprising: prior to sending the data including the data band and the associated parity sector to the host device, performing, by the controller, a track error correction process to correct the at least one controller-correctable error.

### EXAMPLE 5

The method of any of examples 1-4, wherein each virtual data track of the number of virtual data tracks includes a plurality of readable sectors.

### EXAMPLE 6

The method of any of examples 1-5, wherein the data band has a number of rows equal to a first value and a number of columns equal to a second value, wherein the first value comprises the number of virtual tracks, and wherein the second value comprises a number of sectors per virtual track.

### EXAMPLE 7

The method of any of examples 1-6, wherein the data band has a pre-defined size.

### EXAMPLE 8

The method of any of examples 1-7, wherein sending the data comprises: sending, by the controller, the data including the data band with the error in the at least one sector and the associated parity sector to a host device.

### EXAMPLE 9

A hard disk drive comprising: at least one storage medium; and a controller configured to: cause data including a data band and an associated parity sector to be retrieved from non-volatile memory, wherein the data band comprises a number of virtual data tracks, and wherein each virtual data track comprises a respective plurality of sectors; determine that at least one sector of the respective plurality of sectors includes an error that renders the data in the at least one sector unreadable by the controller; and send the data including the data band and the associated parity sector to a host device.

### EXAMPLE 10

The hard disk drive of example 9, further comprising: determine a logical block address of each respective sector of the at least one sector that includes at least one error that renders the data in the at least one sector unreadable by the controller; and create an error location list comprising each of the determined logical block addresses.

### EXAMPLE 11

The hard disk drive of example 10, further comprising: send the error location list to the host device.

### EXAMPLE 12

The hard disk drive of any of examples 9-11, wherein a virtual data track in the data band includes at least one controller-correctable error different from the determined error in the at least one sector, the method further comprising: prior to sending the data including the data band and the associated parity sector to the host device, perform a track error correction process to correct the at least one controller-correctable error.

### EXAMPLE 13

The hard disk drive of any of examples 9-12, wherein each virtual data track of the number of virtual data tracks includes a plurality of readable sectors.

### EXAMPLE 14

The hard disk drive of any of examples 9-13, wherein the data band has a number of rows equal to a first value and a number of columns equal to a second value, wherein the first value comprises the number of virtual tracks, and wherein the second value comprises a number of sectors per virtual track.

### EXAMPLE 15

The hard disk drive of any of examples 9-14, wherein the data. band has a pre-defined size.

### EXAMPLE 16

The hard disk drive of any of examples 9-15, wherein sending the data comprises: send the data including the data band with the error in the at least one sector and the associated parity sector to a host device.

### EXAMPLE 17

A device comprising: means for causing data including a data band and an associated parity sector to be retrieved from non-volatile memory, wherein the data band comprises a number of virtual data tracks, and wherein each virtual data track comprises a respective plurality of sectors means for determining that at least one sector of the respective plurality of sectors includes an error that renders the data in the at least one sector unreadable by the controller; and means for sending the data including the data band and the associated parity sector to a host device.

### EXAMPLE 18

The device of example 17, further comprising: means for determining a logical block address of each respective sector of the at least one sector that includes at least one error that renders the data in the at least one sector unreadable by the controller; and means for creating an error location list comprising each of the determined logical block addresses.

### EXAMPLE 19

The device of example 18, further comprising: means for sending the error location list to the host device.

### EXAMPLE 20

The device of any of examples 17-19, wherein a virtual data track in the data band includes at least one controller-correctable error different from the determined error in the at least one sector, the method further comprising: prior to sending the data including the data band and the associated parity sector to the host device, means for performing a track error correction process to correct the at least one controller-correctable error.

### EXAMPLE 21

The device of any of examples 17-20, wherein each virtual data track of the number of virtual data tracks includes a plurality of readable sectors.

### EXAMPLE 22

The device of any of examples 17-21, wherein the data band has a number of rows equal to a first value and a number of columns equal to a second value, wherein the first value comprises the number of virtual tracks, and wherein the second value comprises a number of sectors per virtual track.

### EXAMPLE 23

The device of any of examples 17-22, wherein the data band has a pre-defined size.

### EXAMPLE 24

The device of any of examples 17-23, wherein the means for sending the data comprises: means for sending the data including the data band with the error in the at least one sector and the associated parity sector to a host device.

### EXAMPLE 25

A computer-readable storage medium comprising instructions that, when executed, cause a controller of a hard disk drive to: cause data including a data band and an associated parity sector to be retrieved from non-volatile memory, wherein the data band comprises a number of virtual data tracks, and wherein each virtual data track comprises a respective plurality of sectors; determine that at least one sector of the respective plurality of sectors includes an error that renders the data in the at least one sector unreadable by the controller; and send the data. including the data band and the associated parity sector to a host device.

### EXAMPLE 26

The computer-readable storage medium of example 25, further comprising: determine a logical block address of each respective sector of the at least one sector that includes at least one error that renders the data in the at least one sector unreadable by the controller; create an error location list comprising each of the determined logical block addresses; and send the error location list to the host device.

### EXAMPLE 27

The computer-readable storage medium of any of examples 25-26, wherein a virtual data track in the data band includes at least one controller-correctable error different from the determined error in the at least one sector, the method further comprising: prior to sending the data including the data band and the associated parity sector to the host device, perform a track error correction process to correct the at least one controller-correctable error.

### EXAMPLE 28

The computer-readable storage medium of any of examples 25-27, wherein each virtual data track of the number of virtual data tracks includes a plurality of readable sectors.

### EXAMPLE 29

The computer-readable storage medium of any of examples 25-28, wherein the data band has a number of rows equal to a first value and a number of columns equal to a second value, wherein the first value comprises the number of virtual tracks, and wherein the second value comprises a number of sectors per virtual track.

### EXAMPLE 30

The computer-readable storage medium of any of examples 25-29, wherein sending the data comprises: send the data including the data band with the error in the at least one sector and the associated parity sector to a host device.

### EXAMPLE 31

A device comprising means for performing the method of any combination of examples 1-8.

### EXAMPLE 32

A computer-readable storage medium encoded with instructions that, when executed, cause at least one processor of a computing device to perform the method of any combination of examples 1-8.

### EXAMPLE 33

A device comprising at least one module operable by one or more processors to perform the method of any combination of examples 1-8.

### EXAMPLE 34

A hard disk drive comprising: at least one storage medium; and a controller configured to: cause a data block to be retrieved from non-volatile memory, wherein the data block includes an error; and send the data block that includes the error to a host device.

### EXAMPLE 35

The hard disk drive claim of example 34, wherein the controller is further configured to: send an indication to the host device that the data block includes the error.

### EXAMPLE 36

The hard disk drive of example 35, wherein the indication comprises a flag.

### EXAMPLE 37

The hard disk drive of example 35, wherein the indication comprises a logical block address indicating a position of the data block in a data band.

### EXAMPLE 38

The hard disk drive of any of examples 34-37, wherein the data block comprises an unreadable sector of a virtual data track.

### EXAMPLE 39

A method for performing the function of any combination of examples 34-38.

### EXAMPLE 40

A computer-readable storage medium encoded with instructions that, when executed, cause at least one processor of a computing device to perform the techniques of any combination of examples 34-38.

### EXAMPLE 41

A device comprising means for performing the techniques of any combination of examples 34-38.

### EXAMPLE 42

A device comprising at least one module operable by one or more processors to perform the techniques of any combination of examples 34-38,

The techniques described in this disclosure may be implemented, at least in part, in hardware, software, firmware, or any combination thereof. For example, various aspects of the described techniques may be implemented within one or more processing units, including one or more microprocessing units, digital signal processing units (DSPs), application specific integrated circuits (ASICs), field programmable gate arrays (FPGAs), or any other equivalent integrated or discrete logic circuitry, as well as any combinations of such components. The term “processing unit” or “processing circuitry” may generally refer to any of the foregoing logic circuitry, alone or in combination with other logic circuitry, or any other equivalent circuitry. A control unit including hardware may also perform one or more of the techniques of this disclosure.

Such hardware, software, and firmware may be implemented within the same device or within separate devices to support the various techniques described in this disclosure. In addition, any of the described units, modules or components may be implemented together or separately as discrete but interoperable logic devices. Depiction of different features as modules or units is intended to highlight different functional aspects and does not necessarily imply that such modules or units must be realized by separate hardware, firmware, or software components. Rather, functionality associated with one or more modules or units may be performed by separate hardware, firmware, or software components, or integrated within common or separate hardware, firmware, or software components.

The techniques described in this disclosure may also be embodied or encoded in an article of manufacture including a computer-readable storage medium encoded with instructions. Instructions embedded or encoded in an article of manufacture including a computer-readable storage medium encoded, may cause one or more programmable processing units, or other processing units, to implement one or more of the techniques described herein, such as when instructions included or encoded in the computer-readable storage medium are executed by the one or more processing units. Computer readable storage media may include random access memory (RAM), read only memory (ROM), programmable read only memory (PROM), erasable programmable read only memory (EPROM), electronically erasable programmable read only memory (EEPROM), flash memory, a hard disk, a compact disk ROM (CD-ROM), a floppy disk, a cassette, magnetic media, optical media, or other computer readable media. In some examples, an article of manufacture may include one or more computer-readable storage media.

In some examples, a computer-readable storage medium may include a non-transitory medium. The term “non-transitory” may indicate that the storage medium is not embodied in a carrier wave or a propagated signal. In certain examples, a non-transitory storage medium may store data that can, over time, change (e.g., in RAM or cache).

Various examples of the disclosure have been described. Any combination of the described systems, operations, or functions is contemplated. These and other examples are within the scope of the following claims.

1. A method comprising:
causing, by a controller of a hard disk drive, data including a data band and an associated parity sector to be retrieved from non-volatile memory, wherein the data band comprises a number of virtual data tracks, and wherein each virtual data track comprises a respective plurality of sectors;
determining, by the controller, that at least one sector of the respective plurality of sectors includes an error that renders the data in the at least one sector unreadable by the controller; and
sending, by the controller, the data including the data band with the error in the at least one sector and the associated parity sector to a host device.

2. The method of claim 1. further comprising:
determining, by the controller, a logical block address of each respective sector of the at least one sector that includes at least one error that renders the data in the at least one sector unreadable by the controller; and
creating, by the controller, an error location list comprising each of the determined logical block addresses.

3. The method of claim 2. further comprising:
sending, by the controller, the error location list to the host device.

4. The method of claim 1, wherein a portion of the determined errors in the at least one sector a virtual data track in the data band includes at least one controller-correctable error different from the determined error in the at least one sector, the method further comprising:
prior to sending the data including the data band and the associated parity sector to the host device, performing, by the controller, a track error correction process to correct the at least one controller-correctable error.

5. The method of claim I, wherein each virtual data track of the number of virtual data tracks includes a plurality of readable sectors.

6. A hard disk drive comprising:
at least one storage medium; and
a controller configured to:
cause data including a data band and an associated parity sector to be retrieved from non-volatile memory, wherein the data band comprises a number of virtual data tracks, and wherein each virtual data track comprises a respective plurality of sectors;
determine that at least one sector of the respective plurality of sectors includes an error that renders the data in the at least one sector unreadable by the controller; and
send the data including the data band with the error in the at least one sector and the associated parity sector to a host device.

7. The hard disk drive of claim 6, wherein the controller is further configured to:
determine a logical block address of each respective sector of the at least one sector that includes at least one error that renders the data in the at least one sector unreadable by the controller; and
create an error location list comprising each of the determined logical block addresses.

8. The hard disk drive of claim 7, wherein the controller is further configured to:
send the error location list to the host device.

9. The hard disk drive of claim 6, wherein a virtual data track in the data band includes at least one controller-correctable error different from the determined error in the at least one sector, wherein the controller is further configured to:
prior to sending the data including the data band and the associated parity sector to the host device, perform a track error correction process to correct the at least one controller-correctable error.

10. The hard disk drive of claim 6, wherein each virtual data track of the number of virtual data tracks includes a plurality of readable sectors.

11. A device comprising:
means for causing data including a data band and an associated parity sector to be retrieved from non-volatile memory, wherein the data band comprises a number of virtual data tracks, and wherein each virtual data track comprises a respective plurality of sectors;
means for determining that at least one sector of the respective plurality of sectors includes an error that renders the data in the at least one sector unreadable by the controller; and
means for sending the data including the data band with the error in the at least one sector and the associated parity sector to a host device.

12. The device of claim 11, further comprising:
means for determining a logical block address of each respective sector of the at least one sector that includes at least one error that renders the data in the at least one sector unreadable by the controller; and
means for creating an error location list comprising each of the determined logical block addresses.

13. The device of claim 12, further comprising:
means for sending the error location list to the host device.

14. The device of claim 11, wherein a virtual data track in the data hand includes at least one controller-correctable error different from the determined error in the at least one sector, the method further comprising:
prior to sending the data including the data band and the associated parity sector to the host device, means for performing a track error correction process to correct the at least one controller-correctable error.

15. The device of claim 11, wherein each virtual data track of the number of virtual data tracks includes a plurality of readable sectors.

16. A hard disk drive comprising:
at least one storage medium; and
a controller configured to:
cause a data block to be retrieved from non-volatile memory, wherein the data block includes an error; and
send the data block that includes the error to a host device.

17. The hard disk drive of claim 16, wherein the controller is further configured to:
send an indication to the host device that the data block includes the error.

18. The hard disk drive of claim 17, wherein the indication comprises a flag.

19. The hard disk drive of claim 17, wherein the indication comprises a logical block address indicating a position of the data. block in a data band.

20. The hard disk drive of claim 16, wherein the data block comprises an unreadable sector of a virtual data track.
